(19) United States
(12) Patent Application Publication
(10) Pub. No.: US 2020/0377998 A1
(43) Pub. Date: Dec. 3, 2020

(54) APPARATUS FOR IMPROVED FLOW CONTROL IN PROCESS CHAMBERS

(71) Applicant: Applied Materials, Inc., Santa Clara, CA (US)

(72) Inventors: Muhannad Mustafa, Milpitas, CA (US); Muhammad M. Rasheed, San Jose, CA (US)

(73) Assignee: Applied Materials, Inc., Santa Clara, CA (US)

(21) Appl. No.: 16/886,104

(22) Filed: May 28, 2020

Related U.S. Application Data
(60) Provisional application No. 62/853,694, filed on May 28, 2019.

(51) Int. Cl. C23C 16/44; C23C 16/52

(52) U.S. Cl. CPC C23C 16/4412; C23C 16/52

(57) ABSTRACT

Pumping liners for process chambers with slit openings are described. The pumping liners have a ring-shaped body with inner and outer walls. An annular upper channel is formed in the upper portion of the outer wall. The upper channel has a plurality of openings with a height, each opening having an independent width. A lower channel is formed in the lower portion of the outer wall and is separated from the upper channel by a partition. The lower channel is in fluid communication with the upper channel through at least one passage in the partition. A slit valve opening is in the lower portion of the body forming an opening in the outer wall and the inner wall.

### CROSS-REFERENCE TO RELATED APPLICATIONS

This application claims priority to U.S. Provisional Application No. 62/853,694, filed May 28, 2019, the entire disclosure of which is hereby incorporated by reference herein.

### TECHNICAL FIELD

Embodiments of the present disclosure pertain to the field of electronic device manufacturing. More particularly, embodiments of the disclosure are directed to apparatus to improve flow control in processing chambers.

### BACKGROUND

Various processing chambers, for example, Atomic Layer Deposition (ALD) and Chemical Vapor Deposition (CVD) chambers use a pump liner to confine the reactive gases to a reaction space adjacent the substrate surface. The pump liners help contain gases within the reaction space and allow rapid evacuation of gases from the reaction space. The pump liners include a plurality of openings to allow the reaction gases to flow through the liner to exhaust. The pump ports are closer to some of the openings than to others. For example, where the pump port is on one side of the ring-shaped liner, the openings in the liner immediately adjacent the pump port are closer than the openings on the opposite side of the liner. To compensate for the different distances, current processing chamber liners have variable size openings to choke the flow of gases toward the pumping ports. The openings closest to the pump port are smaller than the openings further away from the pump port.

The current pumping liners with variable hole sizes have been used to choke the flow of gases toward the pumping port with smaller holes and allow more flow towards the side of the liner through larger holes to optimize the flow pressure distribution inside the process volume. Because the holes are circular in shape, increasing the area of the hole causes an increase in both height and width of the hole. In situations where a portion of the holes are covered, for example, the bottom half of the holes are covered, the area relationship of the holes is changed in a non-linear manner. This can negatively affect the scalability and consistency of the flow characteristics due to different process volumes for different processes.

Therefore, there is a need in the art for apparatus and methods for providing a uniform flow of gases in the process volume.

### SUMMARY

One or more embodiments of the disclosure are directed to pump liners for a process chamber. The pump liners comprise a ring-shaped body having an inner peripheral wall, an outer peripheral wall, an upper portion and a lower portion. An annular upper channel is formed in the upper portion of the outer peripheral wall and has a plurality of circumferentially spaced openings providing fluid communication between the annular upper channel and the upper portion of the inner peripheral wall. The plurality of openings have a height and each of the openings has an independent width. A lower channel is in the lower portion of the outer peripheral wall separated from the annular upper channel by a partition. The lower channel is in fluid communication with the upper channel through at least one passage in the partition. A slit valve opening is in the lower portion of the body extending from the inner peripheral wall to the outer peripheral wall.

Additional embodiments of the disclosure are directed to pump liners for process chambers. The pump liners comprise a ring-shaped body having an inner peripheral wall, an outer peripheral wall, an upper portion and a lower portion. An annular upper channel is formed in the upper portion of the outer peripheral wall and has a plurality of circumferentially spaced rectangular openings providing fluid communication between the annular upper channel and the upper portion of the inner peripheral wall. Each of the plurality of openings have the same height in the range of 0.2 inches to 0.6 inches and independent widths varying between a largest width and a smallest width. A lower channel is in the lower portion of the outer peripheral wall separated from the annular upper channel by a partition. The lower channel is in fluid communication with the upper channel through at least one passage in the partition. A slit valve opening is in the lower portion of the body extending from the inner peripheral wall to the outer peripheral wall. The slit valve opening at the outer peripheral wall extends from a first side to a second side in the range of 100 degrees to 140 degrees. There is in the range of 4 to 12 different size openings the smallest width adjacent the passage in the partition.

Further embodiments of the disclosure are directed to methods of removing gases from a processing chamber. Reduced pressure is applied to a lower portion of a pump liner comprising a ring-shaped body having an inner peripheral wall, an outer peripheral wall, an upper portion and a lower portion to draw gases from within the inner peripheral wall through circumferentially spaced openings into an annular upper channel formed in the upper portion of the outer peripheral wall of the body to flow through a passage in a partition separating the upper portion from the lower portion to flow into a lower channel in the lower portion of the outer peripheral wall. The plurality of circumferentially spaced openings have equal heights and independent widths ranging from a narrowest width to a widest width, the narrowest width adjacent the passage in the partition.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates an isometric view of a pumping liner according to one or more embodiment of the disclosure;

FIG. 2 illustrates the pumping liner of FIG. 1 viewed at a different angle;

FIG. 3 is an expanded view of Region III from FIG. 1;

FIG. 4 is an expanded view of Region IV from FIG. 2; and

FIG. 5 is a schematic view of a processing chamber incorporating the pumping liner according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas” and the like are used interchangeably to refer to any gaseous species that can react with the substrate surface.

One or more embodiments of the disclosure are directed to pumping liners with variable slit openings. Some embodiments advantageously provide better precursor flow distribution for various process spacing between the showerhead and wafer. Some embodiments advantageously provide slit type openings which are only varied along the width and have a constant height. Some embodiments advantageously provide a pumping liner that does not have flow chocking effects at various reaction space sizes.

Current pumping liners with circular openings cannot be controlled by changing either horizontal or vertical dimensions of the openings. Some embodiments of the disclosure advantageously provide pumping liners that, because the heights of the slits in the pumping liner are the same regardless of the pumping port location, flow distribution can be tuned by only varying hole widths.

In slit type pumping liners, openings only vary along width based on skewness of flow pressure distribution. The height for all slit openings will remain the same. At various process spacing (distance between wafer and showerhead), the liner opening will be the same along vertical direction for all of the openings, unlike circular holes. Slit type liner openings have no flow choking effects at various process spacing. The pumping liner of various embodiments can be sued with many types of process chambers where smaller process spacing is used.

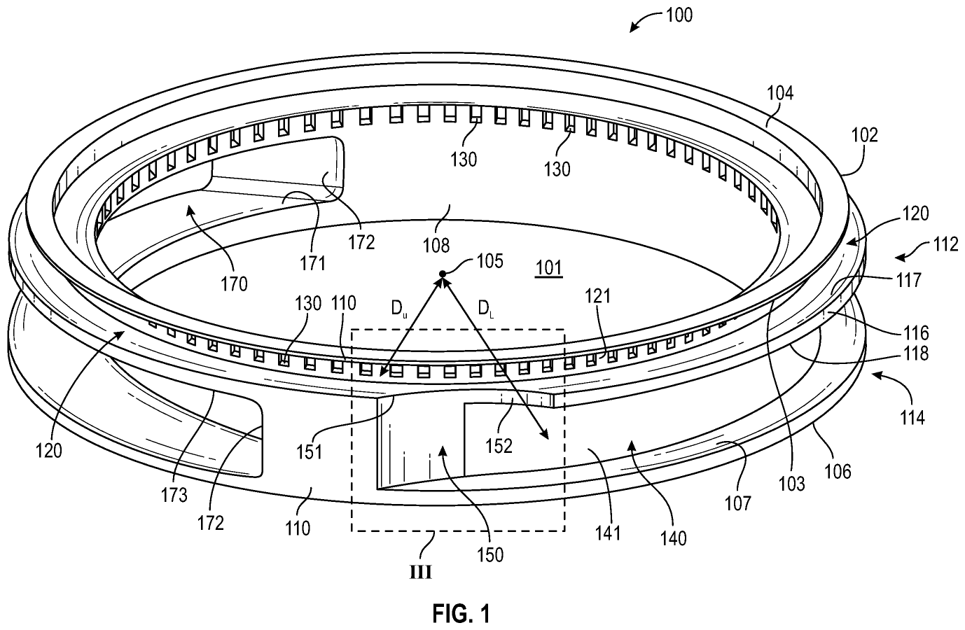

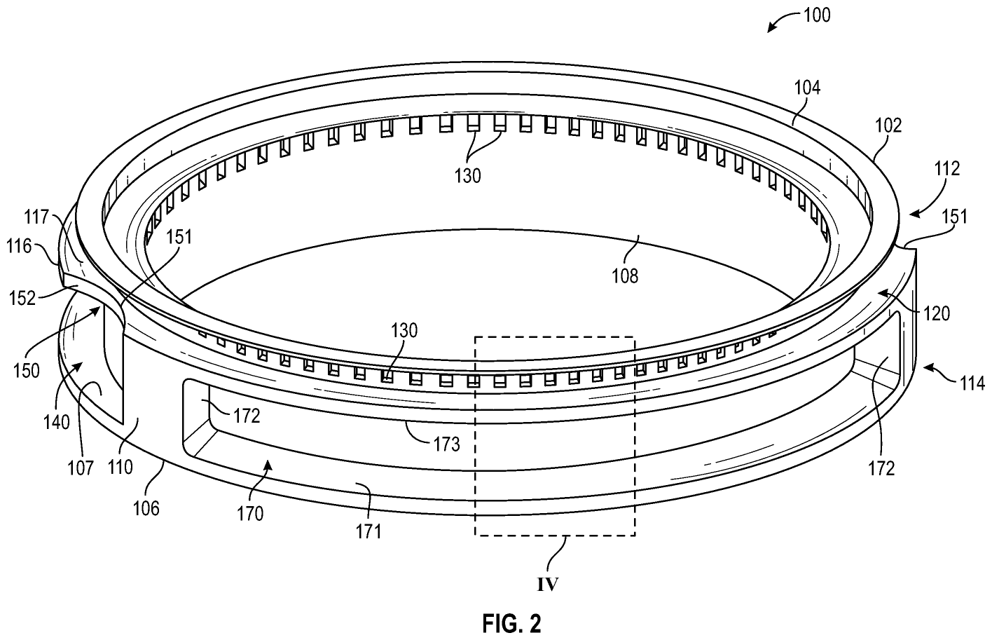

FIGS. 1 and 2 show a parallel projection view of a pump liner 100 for a process chamber in accordance with one or more embodiment of the disclosure. The pump liner 100 includes a ring-shaped body 102 surrounding an inner portion 101. The ring-shaped body 102 has a top 104, bottom 106, inner peripheral wall 108 and an outer peripheral wall 110. The body has an upper portion 112 and a lower portion 114 separated by a partition 116.

An annular upper channel 120 is formed in the upper portion 112 of the outer peripheral wall 110. The annular upper channel 120 of some embodiments extends around the body 102 for 360 degrees. The annular upper channel shown in the Figures is bounded by a bottom face 103 of the top 104 of the body 102 and a top face 117 of the partition 116. The outer peripheral face (outer wall 121) of the upper channel 120 is recessed a distance from the outer peripheral wall 110 defining a depth of the upper channel 120.

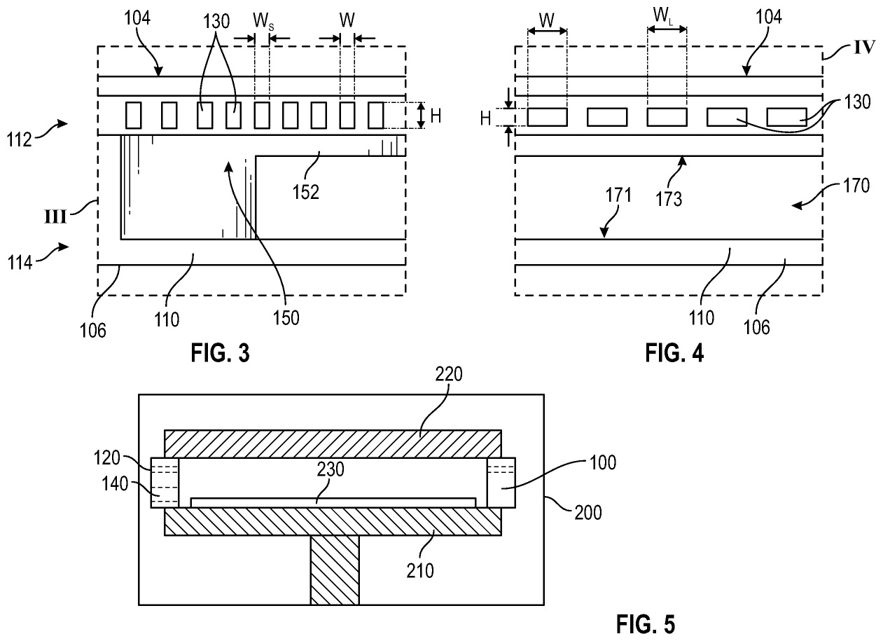

The upper channel 120 has a plurality of circumferentially spaced openings 130 providing fluid communication between the annular upper channel 120 and the upper portion 112 of the inner peripheral wall 108. In some embodiments, each of the plurality of openings 130 has the same height H (see FIGS. 3 and 4). In some embodiments, each of the openings 130 has an independent width W (also illustrated in FIGS. 3 and 4).

Referring back to FIGS. 1 and 2, the pump liner 100 includes a lower channel 140 in the lower portion 114 of the outer peripheral wall 110. The lower channel 140 is separated from the annular upper channel 120 by the partition 116. The height of the lower channel 140 is defined by the distance between the lower face 118 of the partition 116 and the upper face 107 of the bottom 106 of the body. The outer peripheral face (outer wall 141) of the lower channel 140 is recessed a distance from the outer peripheral wall 110 defining a depth of the lower channel 140.

In the illustrated embodiment, the outer wall 121 of the upper channel 120 has a radial distance D_{U} from a center 105 of the ring-shaped body 102 that is smaller than a radial distance D_{L} of the outer wall 141 of the lower channel 140. Stated differently, in some embodiments, the depth of the upper channel 120 is greater than the depth of the lower channel 140. The skilled artisan will recognize that the center 105 marked on the Figures is not an actual physical point but a radial center of the ring-shaped body 102.

In some embodiments, the outer wall 121 of the upper channel 120 has a radial distance D_{U} from the center 105 of the ring-shaped body 102 that is equal to or greater than the radial distance D_{L} of the outer wall 141 of the lower channel 140. Stated differently, in some embodiments, the depth of the upper channel 120 is equal to or less than the depth of the lower channel 140.

The lower channel 140 is in fluid communication with the upper channel 120 through at least one passage 150 in the partition 116. The passage 150 can be any suitable shape and size to allow sufficient conduction of gases through the passage 150. In some embodiments, the passage 150 in the partition 116 is an arc-shaped segment 151 with a concave surface 152 facing the outer peripheral wall 110.

The openings 130 allow a gas within the inner portion 101 of the pump liner 100 to pass into the upper channel 120. The sizes of the openings 130 can be varied to change the conductance of gases through the openings 130 at various angular positions. For example, the openings 130 adjacent the passage 150 can be smaller than the openings further away from the passage 150.

The openings 130 of some embodiments are rectangular in shape. As used in this manner, the term “rectangular” means a quadrilateral with two sets of parallel sides so that each set of parallel sides are perpendicular to the other set of parallel sides. A rectangular shape according to one or more embodiment has rounded corners or corners having an intersection angle of 90 degrees, or 85-95 degrees, or 87-93 degrees, or 88-92 degrees, or 89-91 degrees.

Referring to FIGS. 3 and 4, according to some embodiments, the width W of the openings 130 varies between a largest width W_{L} and a smallest width W_{S}. In some embodiments, the smallest width WS is adjacent the passage 150 in the partition 116. The height H of the openings 130 are substantially the same, meaning that the height of any opening 130 is within 5%, 2%, 1%, or 0.5% of the average height of the openings 130. In some embodiments, the height H of the openings 130 is in the range of 0.1 inches to 0.8 inches, or in the range of 0.2 inches to 0.6 inches, or in the range of 0.25 inches to 0.55 inches.

The number of openings 130 can be varied to allow control of gas conductance. In some embodiments, there are in the range of 4 to 256 openings, or in the range of 36 to 144 openings. In some embodiments, there are greater than or equal to 4, 8, 16, 24, 30, 36, 48, 60, 72, 84, 90, 120, 150 or 180 openings.

The openings 130 of some embodiments are arranged in groups of different sizes. For example, a group of openings adjacent the passage 150 can have the same smallest width W_{S}, and a group of openings centered 90 degrees from the passage can have the same largest width W_{L}. In some embodiments, there are in the range of 2 to 24 different size openings, or in the range of 3 to 18 openings, or in the range of 4 to 12 openings, or in the range of 6 to 10 openings.

Referring back to FIGS. 1 and 2, the pump liner 100 of some embodiments includes a slit valve opening 170 in the lower portion 114 of the body 102. The slit valve opening 170 extends through the body 102 from the inner peripheral wall 108 to the outer peripheral wall 110. The slit valve opening 170 has a bottom face 171, sides 172 and a top face 173. The sides 172 are also referred to as a first side and a second side.

In some embodiments, the slit valve opening 170 has a width sufficient to permit a semiconductor wafer to be transferred therethrough. For example, if the semiconductor wafers being processed have a diameter of 300 mm, the width of the slit valve opening 170 is at least 300 mm between the closest points. In some embodiments, the slit valve opening 170 has a height sufficient to allow a robot end effector supporting a semiconductor wafer to be transferred therethrough.

In some embodiments, the slit valve opening 170 in the outer peripheral wall 110 extends in the range of 80 degrees to 180 degrees, or in the range of 90 degrees to 160 degrees, or in the range of 100 degrees to 140 degrees of the ring-shaped body 102. In some embodiments, the lower channel 140 extends around the outer peripheral wall 110 in the range of 150 degrees to 250 degrees, or in the range of 200 degrees to 225 degrees.

Referring to FIG. 5, one or more embodiments of the disclosure are directed to processing chambers 200 comprising a pump liner 100 as described herein. The processing chamber 200 includes a gas distribution assembly 220 and a substrate support 210 having a support surface facing the gas distribution assembly to support a substrate 230 during processing. The pump liner 100 is around and/or between the gas distribution assembly 220 and the substrate support 210.

One or more embodiments of the disclosure are directed to methods of removing gases from a processing chamber. A reduced pressure is applied to a lower portion of the pump liner 100, as illustrated in FIGS. 1 through 4. The reduced pressure can be applied using any suitable technique or apparatus known to the skilled artisan including, but not limited to, vacuum pumps. The reduced pressure draws gases from within the inner peripheral wall through circumferentially spaced openings in the annular upper channel into the annular upper channel, through at least one passage in a partition to a lower channel in the lower portion of the liner.

In the foregoing specification, embodiments of the disclosure have been described with reference to specific exemplary embodiments thereof. It will be evident that various modifications may be made thereto without departing from the broader spirit and scope of the embodiments of the disclosure as set forth in the following claims. The specification and drawings are, accordingly, to be regarded in an illustrative sense rather than a restrictive sense.

What is claimed is:

1. A pump liner for a process chamber, the pump liner comprising:
a ring-shaped body having an inner peripheral wall, an outer peripheral wall, an upper portion and a lower portion;
an annular upper channel formed in the upper portion of the outer peripheral wall and having a plurality of circumferentially spaced openings providing fluid communication between the annular upper channel and the upper portion of the inner peripheral wall, the plurality of openings having a height and each of the openings having an independent width;
a lower channel in the lower portion of the outer peripheral wall separated from the annular upper channel by a partition, the lower channel in fluid communication with the upper channel through at least one passage in the partition; and
a slit valve opening in the lower portion of the body extending from the inner peripheral wall to the outer peripheral wall.

2. The pump liner of claim 1, wherein the width of the openings varies between a largest width and a smallest width, the smallest width adjacent the passage in the partition.

3. The pump liner of claim 1, wherein the height of the openings is in the range of 0.1 inch to 0.8 inches.

4. The pump liner of claim 3, wherein the height of the openings is in the range of 0.2 inches to 0.6 inches.

5. The pump liner of claim 1, wherein the outer wall of the upper channel has a radial distance from a center of the ring-shaped body that is smaller than a radial distance of the outer wall of the lower channel.

6. The pump liner of claim 1, wherein the slit valve opening has a width sufficient to permit a semiconductor wafer to be transferred therethrough.

7. The pump liner of claim 6, wherein the slit valve opening has a height sufficient to allow a robot end effector supporting a semiconductor wafer to be transferred therethrough.

8. The pump liner of claim 1, wherein the slit valve opening in the outer peripheral wall extends in the range of 100 degrees to 140 degrees of the ring-shaped body.

9. The pump liner of claim 1, wherein the lower channel extends around the outer peripheral wall in the range of 150 degrees to 250 degrees.

10. The pump liner of claim 9, wherein the lower channel extends around the outer peripheral wall in the range of 200 degrees to 225 degrees.

11. The pump liner of claim 1, wherein the openings are rectangular in shape.

12. The pump liner of claim 11, wherein there are in the range of 4 to 256 openings.

13. The pump liner of claim 12, wherein there are in the range of 36 to 144 openings.

14. The pump liner of claim 12, wherein there are in the range of 2 to 24 different size openings.

15. The pump liner of claim 14, wherein there are in the range of 4 to 12 different size openings.

16. The pump liner of claim 1, wherein the passage in the partition is an arc-shaped segment with a concave surface facing the outer peripheral wall.

17. A processing chamber comprising:
a gas distribution assembly;
a substrate support having a support surface facing the gas distribution assembly; and
the pump liner of claim 1.

18. A pump liner for a process chamber, the pump liner comprising:
a ring-shaped body having an inner peripheral wall, an outer peripheral wall, an upper portion and a lower portion;
an annular upper channel formed in the upper portion of the outer peripheral wall and having a plurality of circumferentially spaced rectangular openings providing fluid communication between the annular upper channel and the upper portion of the inner peripheral wall, each of the plurality of openings having the same height in the range of 0.2 inches to 0.6 inches and independent widths varying between a largest width and a smallest width;
a lower channel in the lower portion of the outer peripheral wall separated from the annular upper channel by a partition, the lower channel in fluid communication with the upper channel through at least one passage in the partition; and
a slit valve opening in the lower portion of the body extending from the inner peripheral wall to the outer peripheral wall, the slit valve opening at the outer peripheral wall extends from a first side to a second side in the range of 100 degrees to 140 degrees,
wherein there are in the range of 4 to 12 different size openings the smallest width adjacent the passage in the partition.

19. A processing chamber comprising:
a gas distribution assembly;
a substrate support having a support surface facing the gas distribution assembly; and
the pump liner of claim 18.

20. A method of removing gases from a processing chamber, the method comprising:
applying reduced pressure to a lower portion of a pump liner comprising a ring-shaped body having an inner peripheral wall, an outer peripheral wall, an upper portion and a lower portion to draw gases from within the inner peripheral wall through circumferentially spaced openings into an annular upper channel formed in the upper portion of the outer peripheral wall of the body to flow through a passage in a partition separating the upper portion from the lower portion to flow into a lower channel in the lower portion of the outer peripheral wall,
wherein the plurality of circumferentially spaced openings have equal heights and independent widths ranging from a narrowest width to a widest width, the narrowest width adjacent the passage in the partition.
